(19) United States
(12) Patent Application Publication
(10) Pub. No.: US 2026/0336066 A1
(43) Pub. Date: Oct. 29, 2026

(54) CLAMP DEVICE, CONTROL METHOD FOR SAME AND RECORDING MEDIUM

(71) Applicant: SHINKAWA LTD., Tokyo (JP)

(72) Inventor: Yohei Uchida, Tokyo (JP)

(73) Assignee: SHINKAWA LTD., Tokyo (JP)

(21) Appl. No.: 19/123,057

(22) PCT Filed: Aug. 30, 2023
(86) PCT No.: PCT/JP2023/031523

§ 371 Date: Apr. 21, 2025

(30) Foreign Application Priority Data
Nov. 8, 2022 (JP) 2022-178998

(51) Int. Cl. B25B 5/06; H10W 72/00

(52) U.S. Cl. CPC B25B 5/06; H10W 72/07141

(57) ABSTRACT

A wire clamp device (70) includes: a pair of arm units (72a, 72b); a drive unit (76) having a piezoelectric element (80); a supply unit (90a) that is configured to be able to supply a drive voltage to the piezoelectric element (80) and that increases or lowers a voltage of a DC component in a state in which the frequency of an AC component has been set to the resonance frequency (fr) of the pair of arm units (72a, 72b); a detection unit (90b) that detects an output signal outputted from the driven piezoelectric element (80); and a determination unit (90c) that determines the open/close state of the pair of arm units (72a, 72b) on the basis of the occurrence situation of a harmonic component at the resonance frequency in the output signal.

### TECHNICAL FIELD

The present invention relates to a clamp device, and a control method and a control program for the same.

### DESCRIPTION OF RELATED ART

The clamp device, for example, includes a pair of arm units that clamp a workpiece, a drive unit having a piezoelectric element that opens and closes the pair of arm units, and a supply unit that supplies a voltage to a piezoelectric element. For example, when performing a test or calibration of the clamping operation of the pair of arm units, a function to determine the open/close state of the pair of arm units may be required for the clamp device.

For example, Patent Literature 1 discloses a calibration method including: a step of driving a piezoelectric element by applying a predetermined frequency to vibrate a pair of arm units in an opening/closing direction; a step of detecting whether or not tip units of the pair of arm units have collided based on an output current output from the piezoelectric element when the pair of arm units are vibrating in the opening/closing direction; a step of calculating a reference voltage of a closed state in the pair of arm units based on the detection result; and a step of calibrating a drive voltage applied to the piezoelectric element based on the reference voltage.

### RELATED ART

### Patent Literature

Patent Literature 1: International Publication No. WO 2018/038135

### SUMMARY

### Technical Problem

However, in the calibration method described in Patent Literature 1, the determination of the open/close state of the pair of arm units may be affected by differences in machines such as ease of vibration, ease of vibration transmission, and ease of output current detection.

The present invention was made in view of such circumstances, and aims to improve the determination accuracy of the open/close state of a pair of arm units.

### Solution to the Problem

An aspect of the present invention relates to a clamp device which includes: a pair of arm units that clamp a workpiece; a drive unit having a piezoelectric element that opens and closes the pair of arm units; a supply unit which is configured to generate a drive voltage in which an alternating current (AC) component with a variable frequency and a direct current (DC) component with a variable voltage are superimposed, and to supply the drive voltage to the piezoelectric element, and in which the supply unit sets the frequency of the AC component to a resonant frequency of the pair of arm units and increases or lowers the voltage of the DC component; a detection unit that detects an output signal output from the driven piezoelectric element; and a determination unit that determines an open/close state of the pair of arm units based on an occurrence situation of a harmonic component of the resonant frequency in the output signal.

According to the above-mentioned aspect, the open/close state of the pair of arm units is determined based on the occurrence situation of the harmonic component in the output signal, therefore, in the determination of the open/close state, the influence of machine differences such as ease of vibration, ease of vibration transmission, and ease of output signal detection can be reduced.

As an aspect of the above, the clamp device may further include a registration unit that registers a voltage of the DC component voltage when the pair of arm units switch between an open state and a closed state as a reference voltage, and a calibration unit that calibrates an operating voltage to be applied to the piezoelectric element based on the reference voltage.

According to the above-mentioned aspect, based on the determination result of the open/close state with high accuracy, calibration with high accuracy may be performed, therefore, accuracy improvement and stabilization of the opening/closing operation of the clamp device can be attempted.

As an aspect of the above, the detection unit may detect an output current output from the piezoelectric element as the output signal.

According to the above aspect, the output current from the pair of arm units can be expressed using a time derivative of an output voltage, so even if a change in magnitude that is difficult to detect as the output voltage may become a change in magnitude that can be detected as the output current. Therefore, the detection accuracy of the detection unit can be improved, and the accuracy of the calibration can be enhanced.

As an aspect of the above, the determination unit may calculate the intensity of the harmonic component of the resonant frequency in the output signal by performing a Fourier transform on the output current.

According to the above-mentioned aspect, components included in the output signal can be separated based on a frequency, and the intensity of each of the components can be compared.

As an aspect of the above, the determination unit may calculate an intensity ratio of the harmonic component to a fundamental wave component of the resonant frequency in the output signal.

According to the above-mentioned aspect, an open/close state may be determined based on the intensity ratio, which is easier to compare than the harmonic component that is susceptible to noise influence, and the determination accuracy may be improved.

As an aspect of the above, the determination unit may calculate a rate of change of the intensity ratio with respect to a voltage change of the DC component.

According to the above-mentioned aspect, the open/close state may be determined based on the rate of change of the intensity ratio, which is easier to compare than the intensity ratio that is susceptible to noise influence, and the determination accuracy may be improved.

As an aspect of the above, the registration unit may register a first voltage as a reference voltage when the rate of change of the intensity ratio when the voltage of the DC component is changed from the first voltage to a second voltage exceeds a threshold value.

According to the above aspect, when the pair of arm units switch between an open state and a closed state, the rate of change of the intensity ratio changes significantly, therefore, the first voltage when the rate of change of the intensity ratio exceeds the threshold value can be set as the reference voltage.

As an aspect of the above, the registration unit may register, in a case where the pair of arm units are in contact with each other in a closed state, the voltage of the DC component when the pair of arm units switch from a closed state to an open state as a reference voltage for the start of opening of the pair of arm units, and may register the voltage of the DC component when the pair of arm units switch from an open state to a closed state as a reference voltage for the end of closing of the pair of arm units.

According to the above-mentioned aspect, by registering both the reference voltage at the start of opening and the reference voltage at the end of closing, both the operating voltage when opening and the operating voltage when closing of the pair of arm units may be calibrated, thereby attempting further accuracy improvement and stabilization of the opening/closing operation.

As an aspect of the above, the registration unit may register, in a case where the pair of arm units clamp a calibration jig having higher dimensional accuracy than the workpiece in a closed state, a voltage of the DC component when the pair of arm units switch from a closed state to an open state as a reference voltage for the start of opening of the pair of arm units, and may register a voltage of the DC component when the pair of arm units switch from an open state to a closed state as a reference voltage for the end of closing of the pair of arm units.

According to the above-mentioned aspect, by registering both the reference voltage at the start of opening and the reference voltage at the end of closing when clamping the calibration jig, both the operating voltage when opening and the operating voltage when closing of the pair of arm units may be calibrated, thereby attempting further accuracy improvement and stabilization of the opening/closing operation. By clamping the calibration jig with higher dimensional accuracy than the workpiece when determining the reference voltage, the calibration accuracy can be improved compared to clamping the workpiece.

As an aspect of the above, the registration unit may register, in a case where the pair of arm units clamp the workpiece in a closed state, a voltage of the DC component when the pair of arm units switch from a closed state to an open state as a reference voltage for the start of opening of the pair of arm units, and may register a voltage of the DC component when the pair of arm units switch from an open state to a closed state as a reference voltage for the end of closing of the pair of arm units.

According to the above-mentioned aspect, by registering both the reference voltage at the start of opening and the reference voltage at the end of closing when clamping the workpiece, both the operating voltage when opening and the operating voltage when closing of the pair of arm units may be calibrated, thereby attempting further accuracy improvement and stabilization of the opening/closing operation. By clamping the workpiece when determining the reference voltage, compared to clamping the calibration jig, the configuration of the clamp device and the calibration process may be simplified.

As an aspect of the above, the registration unit may register, in a case where the pair of arm units are in contact with each other in a closed state, a voltage of the DC component when the pair of arm units switch between an open state and a closed state as a first reference voltage, and may register, in a case where the pair of arm units clamp a calibration jig having higher dimensional accuracy than the workpiece or the workpiece in a closed state, a voltage of the DC component when the pair of arm units switch between an open state and a closed state as a second reference voltage, and may calculate and register a rate of change of the opening/closing amount of the pair of arm units with respect to the voltage applied to the piezoelectric element based on a voltage difference between the first reference voltage and the second reference voltage and a dimension of the calibration jig or the workpiece in the opening/closing direction of the pair of arm units, and the calibration unit may calibrate the operating voltage applied to the piezoelectric element based on the rate of change of the opening/closing amount.

According to the above-mentioned aspect, by calibrating the opening/closing amount of the pair of arm units with respect to the operating voltage, further accuracy improvement and stabilization of the opening/closing operation can be attempted.

As an aspect of the above, the harmonic component of the resonant frequency may include components of multiple harmonics.

According to the above aspect, since the determination accuracy of the open/close state of the pair of arm units based on the harmonic component is improved, the accuracy of calibration is enhanced, and further accuracy improvement and stabilization of the opening/closing operation can be attempted.

As an aspect of the above, the supply unit may set the voltage of the DC component to a voltage at which the pair of arm units are in an open state, and increase or lower the frequency of the AC component, the determination unit may determine the resonance state of the pair of arm units based on the occurrence situation of components caused by collision of the pair of arm units in the output signal, and the registration unit may register the frequency of the AC component when the resonance state of the pair of arm units becomes strongest as the resonant frequency of the pair of arm units.

According to the above-mentioned aspect, even in cases where the resonant frequency fluctuates due to machine differences or time-dependent changes, the resonant frequency of the pair of arm units before executing the calibration may be determined. Therefore, the accuracy of the calibration can be improved, and further accuracy improvement and stabilization of the opening/closing operation can be attempted.

Another aspect of the present invention relates to a control method for a clamp device which includes a pair of arm units that clamp a workpiece, a drive unit having a piezoelectric element that opens and closes the pair of arm units, and a supply unit configured to generate a drive voltage in which an AC component with a variable frequency and a DC component with a variable voltage are superimposed, and to supply the drive voltage to the piezoelectric element. The control method includes: the frequency of the AC component is set to a resonant frequency of the pair of arm units and the voltage of the DC component is increased or lowered; an output signal output from the driven piezoelectric element is detected; and an open/close state of the pair of arm units is determined based on an occurrence situation of a harmonic component of the resonant frequency in the output signal.

According to the above-mentioned configuration, the open/close state of the pair of arm units is determined based on the occurrence situation of the harmonic component in the output signal, therefore, in the determination of the open/close state, the influence of machine differences such as ease of vibration, ease of vibration transmission, and ease of output signal detection can be reduced.

Another aspect of the present invention relates to a control program for operating a clamp device which includes a pair of arm units for clamping a workpiece, a drive unit having a piezoelectric element for opening and closing the pair of arm units, and a supply unit configured to generate a drive voltage in which an AC component with a variable frequency and a DC component with a variable voltage are superimposed, and to supply the drive voltage to the piezoelectric element. The control program causes a computer to execute: setting the frequency of the AC component to a resonant frequency of the pair of arm units and increasing or lowering the voltage of the DC component; detecting an output signal output from the driven piezoelectric element; and determining an open/close state of the pair of arm units based on an occurrence situation of a harmonic component of the resonant frequency in the output signal.

According to the above-mentioned configuration, the open/close state of the pair of arm units is determined based on the occurrence situation of the harmonic component in the output signal, therefore, in the determination of the open/close state, the influence of machine differences such as ease of vibration, ease of vibration transmission, and ease of output signal detection can be reduced.

### Effects

According to the present invention, improvement of determination accuracy of the open/close state of a pair of arm units can be attempted.

### BRIEF DESCRIPTION OF THE DRAWINGS

FIG. 1 is a diagram showing an overall outline of a wire bonding apparatus according to an embodiment of the present invention.

FIG. 2 is a top surface view of the bonding arm of the wire bonding apparatus in FIG. 1.

FIG. 3 is a bottom surface view of the bonding arm of the wire bonding apparatus in FIG. 1.

FIG. 4 is a perspective view of the wire clamp device of FIG. 1.

FIG. 5 is a flowchart showing a method for registering a resonant frequency.

FIG. 6 is a graph showing the output current Fourier-transformed when the tip units of the arm units collide.

FIG. 7 is a flowchart showing a part of a calibration method for a wire clamp device according to an embodiment of the present invention.

FIG. 8 is a flowchart showing a part of a calibration method for a wire clamp device according to an embodiment of the present invention.

FIG. 9 is a graph showing the output current Fourier-transformed immediately before the arm units become in an open state at the start of opening.

FIG. 10 is a graph showing the output current Fourier-transformed immediately after the arm units become in an open state at the start of opening.

FIG. 11 is a flowchart showing a part of a calibration method for a wire clamp device according to an embodiment of the present invention.

FIG. 12 is a flowchart showing a part of a calibration method for a wire clamp device according to an embodiment of the present invention.

### DESCRIPTION OF EMBODIMENTS

The following describes an embodiment of the present invention. In the following drawings, the same or similar components are represented by the same or similar reference numerals. The drawings are exemplary, and the dimensions and shapes of each of units are schematic. The technical scope of the present invention should not be construed as being limited to the embodiment.

### Wire bonding apparatus>

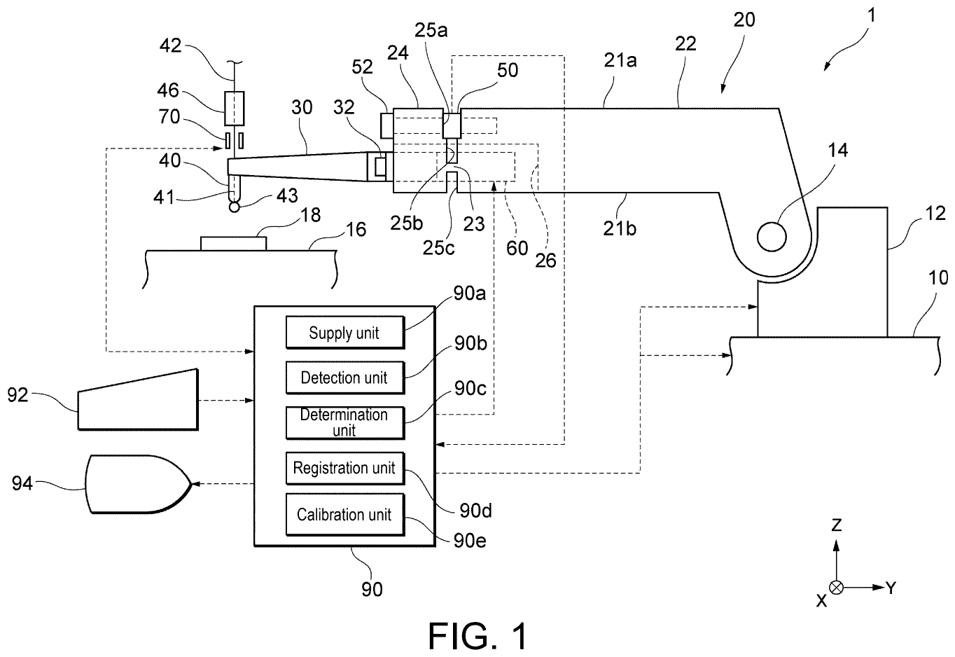

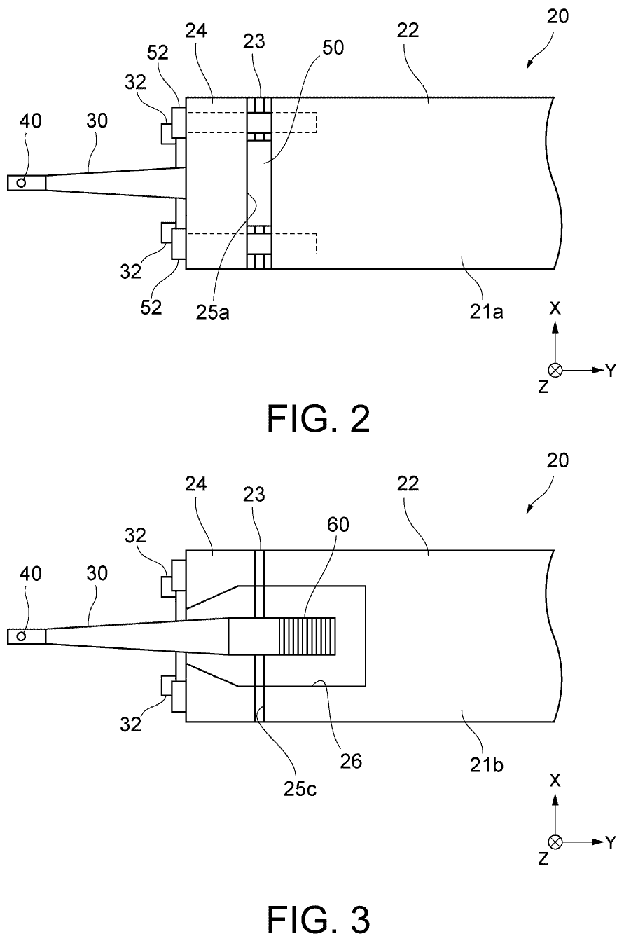

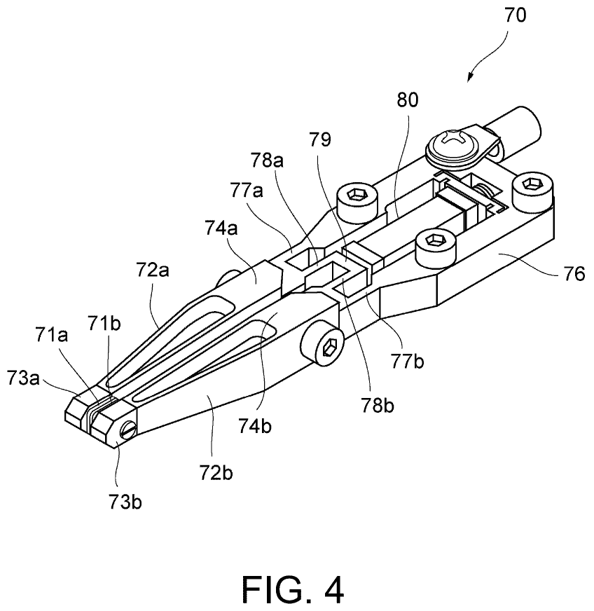

First, referring to FIGS. 1 to 4, the configuration of a wire bonding apparatus 1 according to an embodiment of the present invention will be described. FIG. 1 is a diagram showing an overall schematic view of the wire bonding apparatus according to the embodiment. FIG. 2 is a top surface view of the bonding arm of the wire bonding apparatus in FIG. 1. FIG. 3 is a bottom surface view of the bonding arm of the wire bonding apparatus in FIG. 1. FIG. 4 is a perspective view of the wire clamp device of FIG. 1.

As shown in FIG. 1, the wire bonding apparatus 1 includes an XY drive mechanism 10, a Z drive mechanism 12, a bonding arm 20, an ultrasonic horn 30, a bonding tool 40, a load sensor 50, an ultrasonic transducer 60, a wire clamp device 70, and a wire bonding control unit 90.

The XY drive mechanism 10 is configured to be slidable in an XY-axis direction (direction parallel to the bonding surface), and the XY drive mechanism (linear motor) 10 is provided with a Z drive mechanism (linear motor) 12 capable of swinging the bonding arm 20 in a Z-axis direction (direction perpendicular to the bonding surface).

The bonding arm 20 is supported by a support shaft 14 and is configured to be freely swingable with respect to the XY drive mechanism 10. The bonding arm 20 is formed in a substantially rectangular shape extending from the XY drive mechanism 10 to a bonding stage 16 on which a workpiece (for example, a semiconductor die or substrate) 18, which is the bonding target, is placed. The support shaft 14 is, for example, at approximately the same height as the working surface (bonding surface) of the workpiece 18. The bonding arm 20 includes an arm base end unit 22 attached to the XY drive mechanism 10, an arm tip unit 24 positioned at the tip side of the arm base end unit 22 to which the ultrasonic horn 30 is attached, and a connecting unit 23 that connects the arm base end unit 22 and the arm tip unit 24 and has flexibility. The connecting unit 23 is composed of a slit 25a and a slit 25b of a predetermined width extending from a top surface 21a of the bonding arm 20 towards a bottom surface 21b, and a slit 25c of a predetermined width extending from the bottom surface 21b of the bonding arm 20 towards the top surface 21a. In this way, since the connecting unit 23 is locally configured as a thin-walled unit by each of the slit 25a, the slit 25b, and the slit 25c, the arm tip unit 24 is configured to flex with respect to the arm base end unit 22.

As shown in FIGS. 1 and 3, a concave unit 26 is formed on the bottom surface 21b side of the bonding arm 20, in which the ultrasonic horn 30 is accommodated. The ultrasonic horn 30 is attached to the arm tip unit 24 by horn fixing screws 32 in a state where the ultrasonic horn 30 is accommodated in the concave unit 26 of the bonding arm 20. This ultrasonic horn 30 holds the bonding tool 40 at a tip unit thereof protruding from the concave unit 26, and an ultrasonic transducer 60 that generates ultrasonic vibration is provided in the concave unit 26. Ultrasonic vibration is generated by the ultrasonic transducer 60, which is transmitted to the bonding tool 40 by the ultrasonic horn 30, and ultrasonic vibration can be applied to the bonding target via the bonding tool 40. The ultrasonic transducer 60 is, for example, a piezoelectric transducer.

Also, as shown in FIGS. 1 and 2, on the top surface 21a side of the bonding arm 20, a slit 25a and a slit 25b are formed in order from the top surface 21a toward the bottom surface 21b. The slit 25a of the upper part is formed wider than the slit 25b of the lower part. And in the widely formed slit 25a of the upper part, a load sensor 50 is provided. The load sensor 50 is fixed to the arm tip unit 24 by preload screws 52. The load sensor 50 is disposed to be sandwiched between the arm base end unit 22 and the arm tip unit 24. That is, the load sensor 50 is offset in the direction of approaching and separating from the bonding target from a center axis in a longitudinal direction of the ultrasonic horn 30, and is installed between a rotation center of the bonding arm 20 and a mounting surface of the ultrasonic horn 30 at the arm tip unit 24 (i.e., the tip surface on the bonding tool 40 side of the arm tip unit 24). And as described above, since the ultrasonic horn 30 holding the bonding tool 40 is attached to the arm tip unit 24, when a load is applied to the tip of the bonding tool 40 due to the reaction force from the bonding target, the arm tip unit 24 flexes relative to the arm base end unit 22, and the load at the load sensor 50 may be detected. The load sensor 50 is, for example, a piezoelectric element load sensor.

The bonding tool 40 is for inserting a wire 42, and is, for example, a capillary

with an insertion hole 41 provided. In this case, the wire 42 used for bonding is inserted through the insertion hole 41 of the bonding tool 40, and is configured to be able to feed out a part of the wire 42 from the tip thereof. Additionally, a pressing unit for pressing the wire 42 is provided at the tip of the bonding tool 40. The pressing unit has a rotationally symmetric shape around the axial direction of the insertion hole 41 of the bonding tool 40, and has a pressing surface on the bottom surface surrounding the insertion hole 41.

The bonding tool 40 is detachably attached to the ultrasonic horn 30 by spring force or the like. Additionally, above the bonding tool 40, a wire clamp device 70 is provided, and the wire clamp device 70 is configured to restrain or release the wire 42 at a predetermined timing. Further above the wire clamp device 70, a wire tensioner 46 is provided, and the wire tensioner 46 is configured to have the wire 42 inserted therethrough and to apply appropriate tension to the wire 42 during bonding.

The material of the wire 42 is appropriately selected based on factors such as ease of processing and low electrical resistance, and for example, gold (Au), copper (Cu), or silver (Ag) are used. It should be noted that the wire 42 is bonded to a first bond point of the workpiece 18 with a free air ball 43 that extends from the tip of the bonding tool 40.

Here, referring to FIG. 4, details of the wire clamp device 70 according to the embodiment will be described. The wire clamp device 70 corresponds to an example of a clamp device for clamping a workpiece. In the wire clamp device 70, the workpiece is a wire. The wire clamp device 70 includes a pair of arm units 72a and 72b, and a drive unit 76 attached to the body of the wire bonding apparatus 1. The pair of arm units 72a and 72b have tip units 73a and 73b for clamping the wire 42, and base end units 74a and 74b, and extend in a direction substantially perpendicular to the wire axis direction from the tip units 73a and 73b toward the base end units 74a and 74b. On the mutually opposing surfaces of the tip units 73a and 73b, clamp pieces 71a and 71b are provided at which the wire 42 comes into contact. Additionally, in the drive unit 76, a piezoelectric element 80 is provided for opening and closing the tip units 73a and 73b of the pair of arm units 72a and 72b. The opening and closing operation of the pair of arm units 72a and 72b is controlled by the piezoelectric element 80 being supplied with a drive voltage from the wire bonding control unit 90 (specifically, the supply unit 90a). The end unit of the drive unit 76 opposite to the pair of arm units 72a and 72b is fixed to the body of the wire bonding apparatus 1. In FIG. 1, the wire clamp device 70 is shown in a state viewed from the tip units 73a and 73b side in the extending direction of the pair of arm units 72a and 72b.

The pair of arm units 72a and 72b are connected to the drive unit 76 at the base end units 74a and 74b thereof via multiple connecting units 77a, 77b, 78a, and 78b. Specifically, when viewing the pair of arm units 72a and 72b from above in the wire axis direction, a pair of connecting units 78a and 78b are provided on both outer sides of the pair of arm units 72a and 72b, and a pair of connecting units 77a and 77b are provided at positions sandwiched between the pair of connecting units 78a and 78b. The connecting units are configured as elastically deformable constricted units. Additionally, the pair of connecting units 77a and 77b are connected to each other by an action unit 79. In such configuration, the piezoelectric element 80 is provided with both end units thereof fixed between the drive unit 76 and the action unit 79. By applying a drive voltage to cause the piezoelectric element 80 to extend and contract in the extending direction of the pair of arm units 72a and 72b, each of the connecting unit 77a, 77b, 78a, and 78b elastically deforms to open and close the tip units 73a and 73b of the pair of arm units 72a and 72b. It should be noted that each of the connecting unit 77a, 77b, 78a, and 78b possesses spring properties in the direction of closing the tip units 73a and 73b.

The piezoelectric element 80 is, for example, a laminated piezoelectric actuator in which multiple layers of piezoelectric elements are stacked in a direction connecting the drive unit 76 and the action unit 79.

The pair of arm units 72a and 72b (clamp pieces 71a and 71b, tip units 73a and 73b, and base end units 74a and 74b) are, for example, constructed of a conductive material.

Next, the operation of the wire clamp device 70 will be described. In a state where no voltage is applied to the piezoelectric element 80, a predetermined load is applied to the tip units 73a and 73b of the pair of arm units 72a and 72b in the closing direction. Next, when a drive voltage is applied to the piezoelectric element 80, due to the electrostrictive or magnetostrictive effect, the piezoelectric element 80 extends in the extending direction of the pair of arm units 72a and 72b (in other words, the direction connecting the drive unit 76 and the action unit 79), thereby causing the action unit 79 to move in the direction of the pair of arm units 72 a of 72b. In this way, the connecting units 77a, 77b, 78a and 78b are bent outwardly, and the tip units 73a and 73b become in an open state. The amount of movement of the tip units 73a and 73b at this time corresponds to the amount of extension of the piezoelectric element 80 magnified according to the ratio of the length from the action unit 79 to the connecting units and the length from the connecting units to the tip units 73a and 73b. Here, when the opening/closing amount of the pair of arm units 72a and 72b is defined as the mutual distance between the clamp pieces 71a and 71b in the opening/closing direction, the amount of movement of the tip units 73a and 73b corresponds to the amount of change in the opening/closing amount of the pair of arm units 72a and 72b.

To further elaborate, as the drive voltage applied to the piezoelectric element 80 is increased from zero, the wire clamp load by the tip units 73a and 73b lowers in proportion to the voltage value applied to the piezoelectric element 80, and when the voltage value becomes the reference voltage value, the clamp pieces 71a and 71b of the tip units 73a and 73b are in a state of mutual contact with the wire clamp load being zero. As the voltage value is further increased, the tip units 73a and 73b enter a state where the tip units 73a and 73b open in a direction away from each other. The state where the tip units 73a and 73b are in mutual contact is defined as the “closed state” of the pair of arm units 72a and 72b, and the state where the tip units 73a and 73b are separated from each other is defined as the “open state” of the pair of arm units 72a and 72b.

Referring to FIG. 1 again, the wire bonding apparatus 1 according to the embodiment will be further described. The wire bonding control unit 90 is connected to enable signal transmission and reception between various components such as the XY drive mechanism 10, Z drive mechanism 12, ultrasonic horn 30 (ultrasonic transducer 60), load sensor 50 and wire clamp device 70, and by controlling the operation of the components with the wire bonding control unit 90, the needed processing for wire bonding may be performed.

Moreover, an operation unit 92 for inputting control information and a display unit 94 for outputting control information are connected to the wire bonding control unit 90. This enables an operator to input needed control information by the operation unit 92 while viewing the screen on the display unit 94. It should be noted that the wire bonding control unit 90 is a computer device including a central processing unit (CPU) and memory, etc., and the memory stores a bonding program for performing needed processing for wire bonding in advance and various data processed by each of the components of the wire bonding control unit 90 to be described later. The wire bonding control unit 90 is configured to control the needed operations for performing calibration of the wire clamp device to be described later. For example, the wire bonding control unit 90 executes each of operations for calibration by causing the CPU to execute the program stored in the memory.

The wire bonding control unit 90 according to the embodiment includes a supply unit 90a, a detection unit 90b, a determination unit 90c, a registration unit 90d, and a calibration unit 90e.

The supply unit 90a generates and supplies a direct current or pulsating voltage to the piezoelectric element 80. Specifically, the supply unit 90a supplies a direct current voltage as the operating voltage to the piezoelectric element 80 during the wire bonding process, and supplies a pulsating current with superimposed a direct current (DC) component and an alternating current (AC) component as the drive voltage to the piezoelectric element 80 during the calibration process of the wire clamp device 70. By supplying a pulsating current to the piezoelectric element 80, the direct current component applies a load to the tip units 73a and 73b of the pair of arm units 72a and 72b in the direction opposite to the wire clamp load (opening direction), while the alternating current component of the pulsating current vibrates the tip units 73a and 73b of the pair of arm units 72a and 72b in the opening/closing direction. Here, the voltage of the direct current component of the pulsating current is variable within a range that allows switching between an open state and a closed state of the pair of arm units 72a and 72b. Additionally, the frequency of the alternating current component of the pulsating current is variable within a range that includes a resonant frequency fr determined based on the natural angular frequency of the pair of arm units 72a and 72b. For example, the supply unit 90a gradually or continuously increases or lowers the voltage of the direct current component during one stage of the calibration process. Also, the supply unit 90a gradually or continuously increases or lowers the frequency of the alternating current component during one stage of the calibration process.

The detection unit 90b detects an output current from the piezoelectric element 80 when the pair of arm units 72a and 72b are vibrating in the opening/closing direction due to the piezoelectric element 80 being driven by the supply unit 90a. The output current is an example of an output signal output from the driven piezoelectric element 80. When the pair of arm units 72a and 72b vibrate in the opening/closing direction, a potential difference occurs in the piezoelectric element 80. The potential difference changes depending on whether the pair of arm units 72a and 72b collide with each other or not. Additionally, the potential difference also changes depending on whether the pair of arm units 72a and 72b are in a resonance state or not. The detection unit 90b detects changes in the output current based on such changes in the potential difference of the piezoelectric element 80. The detection unit 90b stores data related to the detected output current in the memory of the wire bonding control unit 90.

The determination unit 90c acquires data related to the output current stored in the memory, and determines the open/close state of the pair of arm units 72a and 72b based on the occurrence situation of a harmonic component of the resonant frequency fr in the output current. When an AC voltage of the resonant frequency fr is applied to the piezoelectric element 80 while the pair of arm units 72a and 72b are in an open state, a harmonic component is detected in the output current in addition to the fundamental wave component of the resonant frequency fr. The harmonic component of the resonant frequency fr included in the output current becomes very small or nearly zero when the pair of arm units 72a and 72b are in a closed state. Utilizing this, the determination unit 90c determines the open/close state of the pair of arm units 72a and 72b.

Specifically, in the supply unit 90a, while setting the frequency of the AC component of the drive voltage to the resonant frequency fr, by varying the voltage of the DC component, in the determination unit 90c, based on the presence or absence and intensity of a harmonic component in the output current, the open/close state of the pair of arm units 72a and 72b is determined.

At this time, the determination unit 90c performs a Fourier transform on the output current, and calculates the intensity of the fundamental wave component of the resonant frequency fr and the intensity of the harmonic component of the resonant frequency fr. Here, the harmonic component of the resonant frequency fr may include multiple higher-order harmonics including a second harmonic f2 of the resonant frequency fr, for example, the harmonic component of the resonant frequency fr includes components of the second harmonic f2, a third harmonic f3, and a fourth harmonic f4. Furthermore, the determination unit 90c calculates the intensity ratio of the harmonic component to the fundamental wave component of the resonant frequency fr, and calculates the rate of change of the intensity ratio with respect to the voltage change of the DC component in the drive voltage. Then, the determination unit 90c determines that an open state and a closed state of the pair of arm units 72a and 72b have switched when the rate of change of the intensity ratio exceeds a threshold value.

Since the intensity of the harmonic component is smaller compared to the intensity of the fundamental wave component, the determination unit 90c improves the determination accuracy by making a determination based on the rate of change of the intensity ratio with respect to the voltage change. However, as long as the determination unit 90c may determine the open/close state of the pair of arm units 72a and 72b, a determination may be made based on the intensity ratio of the harmonic component to the fundamental wave component, or based on the intensity of the harmonic component.

In the step of determining the open/close state of the pair of arm units 72a and 72b, the determination unit may determine the resonance state of the pair of arm units 72a and 72b in order to specify the resonant frequency fr used. For example, the determination unit 90c determines the resonance state of the pair of arm units 72a and 72b based on the occurrence situation of components caused by the collision of the pair of arm units 72a and 72b in the output current detected by the detection unit 90b. When the pair of arm units 72a and 72b in an open state vibrate and collide with each other, the output current includes components caused by the AC component of the drive voltage of the pair of arm units 72a and 72b, as well as a component caused by the mutual collision of the pair of arm units 72a and 72b (hereinafter referred to as “collision component”). Utilizing this, the determination unit 90c determines the resonance state of the pair of arm units 72a and 72b.

Specifically, in the supply unit 90a, the frequency of the AC component of the drive voltage is changed while the voltages of the DC component and AC component of the drive voltage are set so that the pair of arm units 72a and 72b collide with each other when vibrating in a resonant state, but do not collide when vibrating in a non-resonant state. Then, in the determination unit 90c, the open/close state of the pair of arm units 72a and 72b is determined based on the presence or absence and intensity of a collision component in the output current.

At this time, the determination unit 90c performs a Fourier transform on the output current and calculates the intensity of the collision component. Here, a frequency fx of the collision component is higher than the fundamental wave of the resonant frequency fr, for example, about 5 times the height of the resonant frequency fr. The intensity of the collision component is smaller than the intensity of the fundamental wave component of the resonant frequency fr, and larger than the intensity of the harmonic component of the resonant frequency fr. For example, the determination unit 90c determines that the pair of arm units 72a and 72b are vibrating in a resonance state when the intensity of the collision component exceeds a threshold value.

The registration unit 90d registers, based on the determination result of the open/close state of the pair of arm units 72a and 72b by the determination unit 90c, the voltage of the DC component of the drive voltage as a reference voltage when the pair of arm units 72a and 72b switch between an open state and a closed state. Here, the reference voltage in a closed state where the pair of arm units 72a and 72b are in contact with each other corresponds to the DC voltage at the state (zero load point) where the pair of arm units 72a and 72b are in contact with each other with the wire clamp load being substantially zero. Also, the reference voltage in a closed state where the pair of arm units 72a and 72b clamp a wire or a calibration jig with higher dimensional accuracy than the wire corresponds to the DC voltage at the state (zero load point) where the pair of arm units 72a and 72b clamp the wire or the calibration jig with the wire clamp load being substantially zero. Such a reference voltage may be, for example, the reference voltage when the pair of arm units 72a and 72b switch from an open state to a closed state, or may be the reference voltage when the pair of arm units 72a and 72b switch from a closed state to an open state. It should be noted that, in the following, the switching from an open state to a closed state is referred to as “end of closing”, and the switching from a closed state to an open state is referred to as “start of opening”.

The registration unit 90d registers at least one of: the reference voltage at the end of closing and the reference voltage at the start of opening when the pair of arm units 72a and 72b are in contact with each other in a closed state; and the reference voltage at the end of closing and the reference voltage at the start of opening when the pair of arm units 72a and 72b clamp the wire or the calibration jig. The relationship between the voltage applied to the pair of arm units 72a and 72b and the opening/closing amount shows hysteresis. In other words, since the reference voltage at the end of closing and the reference voltage at the start of opening have different values from each other, it is desirable for the registration unit 90d to register both the reference voltage at the end of closing and the reference voltage at the start of opening. In addition to the above-mentioned reference voltages, the registration unit 90d calculates and registers the rate of change of the opening/closing amount of the pair of arm units 72a and 72b with respect to the voltage applied to the piezoelectric element 80. The data registered by the registration unit 90d is stored in the memory of the wire bonding control unit 90. The calculation example of the reference voltage and the rate of change of the opening/closing amount in the registration unit 90d will be described later.

The calibration unit 90e reads out data related to the reference voltage and the rate of change of the opening/closing amount registered by the registration unit 90d from the memory, and calibrates the operating voltage (DC voltage) to be applied to the piezoelectric element 80 in the wire bonding process. In this case, the calibration unit 90e may correct the numerical value of the already set operating voltage, or may newly set the operating voltage to be applied to the piezoelectric element 80. Thus, the operating voltage calibrated by the calibration unit 90e is stored in the memory of the wire bonding control unit 90. Then, in the wire bonding process, the supply unit 90a can read out the calibrated operating voltage stored in the memory and drive the piezoelectric element 80 based on the operating voltage.

### Calibration Method

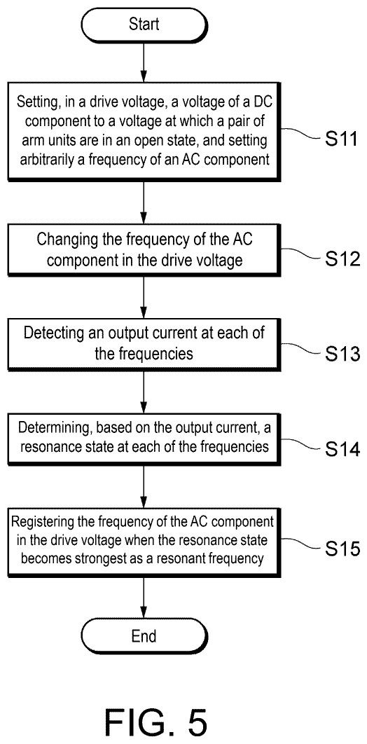

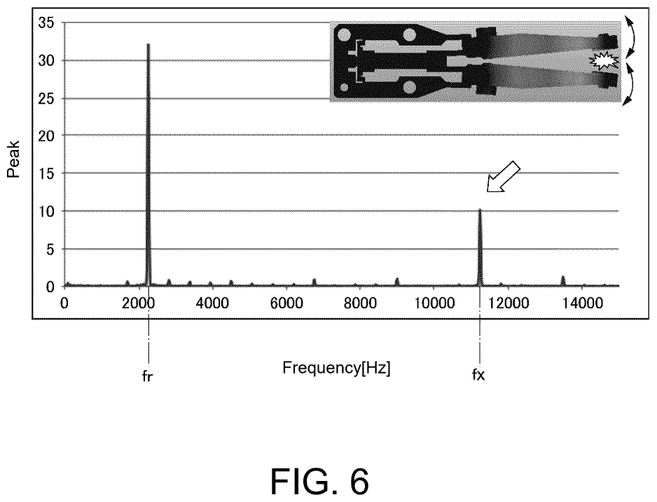

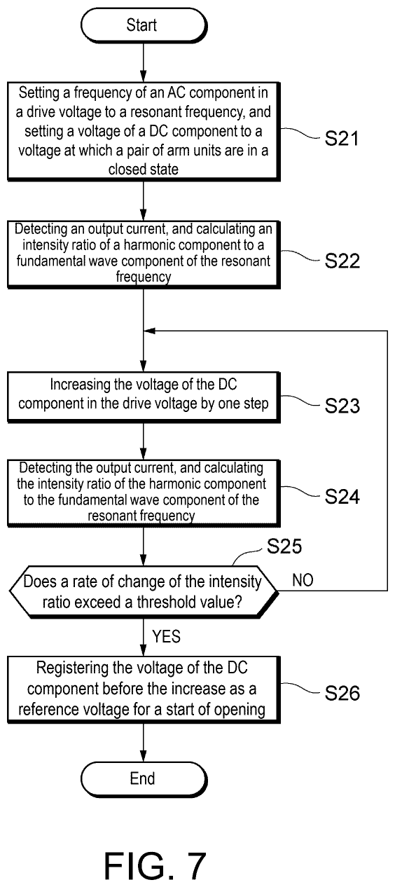

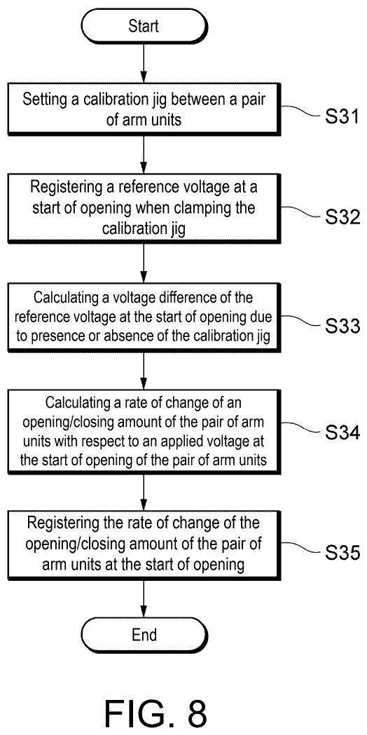

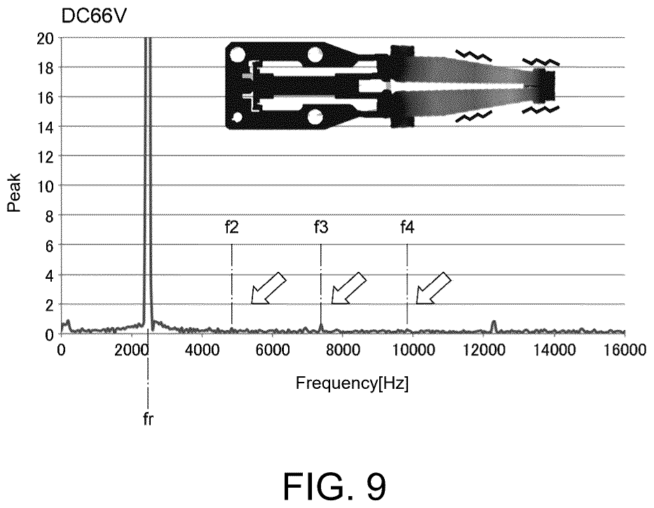

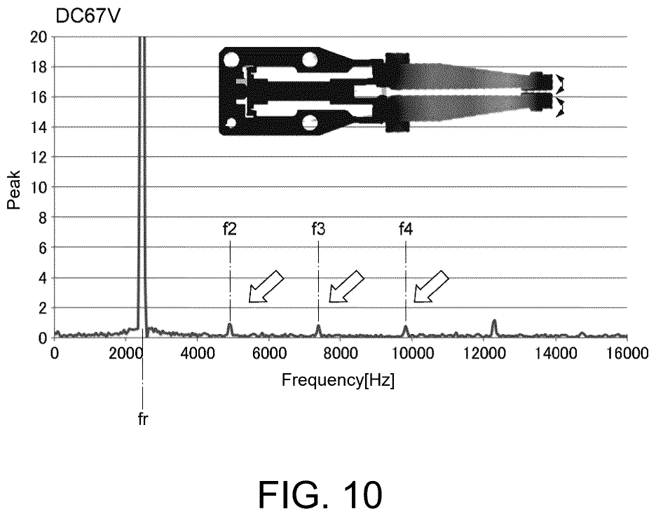

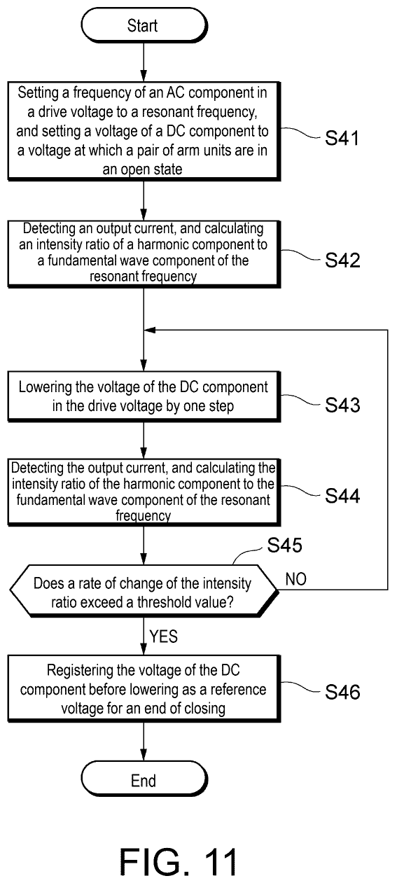

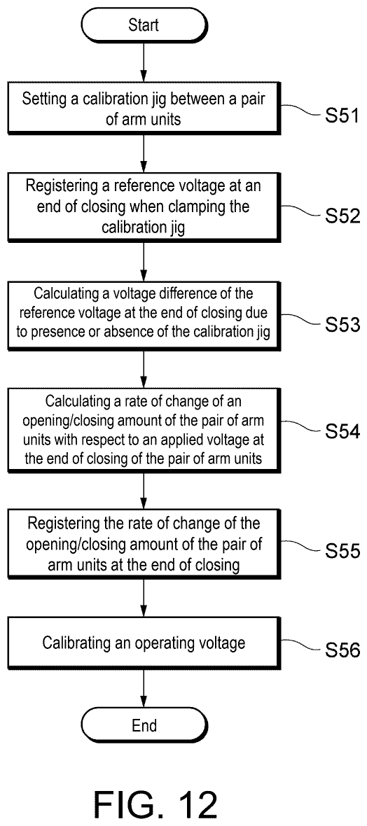

Next, referring to FIGS. 5 to 12, a calibration method using the wire clamp device 70 according to the embodiment will be described. FIG. 5 is a flowchart showing a method for registering a resonant frequency. FIG. 6 is a graph showing the output current Fourier-transformed when the tip units of the arm units collide. FIGS. 7 and 8 are flowcharts showing a part of the calibration method of the wire clamp device according to an embodiment of the present invention. FIGS. 7 and 8 are flowcharts showing a method for registering the rate of change of the reference voltage and opening/closing amount at the start of opening of the pair of arm units 72a and 72b. FIG. 9 is a graph showing the output current Fourier-transformed immediately before the arm units become in an open state at the start of opening. FIG. 10 is a graph showing the output current Fourier-transformed immediately after the arm units become in an open state at the start of opening. FIGS. 11 and 12 are flowcharts showing a part of the calibration method of the wire clamp device according to an embodiment of the present invention. FIGS. 11 and 12 are flowcharts showing a method for registering the rate of change of the reference voltage and opening/closing amount at the end of closing of the pair of arm units 72a and 72b. The graphs shown in FIGS. 6, 9, and 10 are obtained by Fast Fourier Transform (FFT) processing of data sampled at 100 kSPS by a current detection circuit of the output current, where the lateral axis represents frequency and the longitudinal axis represents intensity.

The calibration method according to the embodiment can be performed using the above-mentioned wire bonding apparatus 1. Additionally, the calibration method for the wire clamp device 70 according to the embodiment can be carried out at the end of wire bonding (i.e., before the start of the next wire bonding) or during teaching for wire bonding, etc.

A calibration method according to an aspect of the present invention uses the resonant frequency fr of the pair of arm units 72a and 72b. Therefore, in case the resonant frequency fr fluctuates due to individual differences or time-dependent changes, it is desirable to register the resonant frequency fr immediately before calibration. For this reason, first, referring to FIG. 5, a method for registering the resonant frequency fr of the pair of arm units 72a and 72b will be described. Here, as shown in FIG. 6, it is determined whether the pair of arm units 72a and 72b are vibrating at the resonant frequency fr based on the occurrence situation of the collision component at the frequency fx. It should be noted that if the resonant frequency fr is known, the step of registering the resonant frequency fr may be omitted.

First, in the drive voltage, the voltage of the DC component is set to a voltage at which the pair of arm units 72a and 72b are in an open state, and the frequency of the AC component is set arbitrarily (S11). At this time, the voltage of the AC component of the drive voltage is set to a magnitude .at which the pair of arm units 72a and 72b collide with each other when vibrating in a resonance state, and do not collide when vibrating in a non-resonance state. For example, the voltage of the DC component is set to 138V, and the voltage of the AC component is set to 10V.

Next, the frequency of the AC component in the drive voltage is changed (S12). The supply unit 90a changes the frequency of the AC component over a frequency range that includes the expected resonant frequency fr. For example, the supply unit 90a increases the frequency of the AC component from 1.7 kHz to 2.7 kHz in 0.05 kHz increments. Then, the output current at each of the frequencies is detected (S13).

Next, based on the output current, the resonance state at each of the frequencies is determined (S14). The resonance state is determined based on the intensity of the frequency fx of the collision component shown in FIG. 6. When the frequency fx of the collision component exceeds a threshold value, it is determined that the pair of arm units 72a and 72b are in a resonance state. Then, the frequency of the AC component in the drive voltage when the resonance state becomes strongest is registered as the resonant frequency fr (S15). In other words, the frequency of the AC component when the frequency fx of the collision component becomes strongest is registered as the resonant frequency fr. If merely one frequency of the AC component is determined to be in a resonance state in step S14, the frequency of the AC component is registered as the resonant frequency fr in step S15. The resonant frequency fr is stored in the memory of the wire bonding control unit 90 by the registration unit 90d. The resonant frequency fr is, for example, 2.45 kHz.

Next, referring to FIG. 7, a method for registering a reference voltage for the start of opening when the pair of arm units 72a and 72b do not clamp anything will be described. Here, as shown in FIGS. 9 and 10, based on the occurrence situation of the harmonic component near the frequency f2 (f2≈fr×2) of the second harmonic, near the frequency f3 (f3≈fr×3) of the third harmonic, and near the frequency f4 (f4≈fr×4) of the fourth harmonic of the resonant frequency fr, when a drive voltage including an AC component of the resonant frequency fr is applied, it is determined whether the pair of arm units 72a and 72b are in an open state or a closed state.

First, the frequency of the AC component in the drive voltage is set to the resonant frequency fr, and the voltage of a DC component is set to a voltage at which the pair of arm units 72a and 72b are in a closed state (S21). The resonant frequency fr used here is the one registered in step S15. The supply unit 90a reads the resonant frequency fr from the memory and sets the frequency of the AC component. The supply unit 90a sets the voltage of the DC component lower than the expected reference voltage. For example, the voltage of the DC component is set to 40V, and the voltage of the AC component is set to 8V.

Next, the output current is detected, and the intensity ratio of the harmonic component to the fundamental wave component of the resonant frequency fr is calculated (S22). In the detection unit 90b, the output current detected by the current detection circuit is Fourier transformed, and the peak intensities near 1 times (fundamental wave), 2 times (second harmonic f2), 3 times (third harmonic f3), and 4 times (fourth harmonic f4) of the resonant frequency fr are calculated. The intensity of the harmonic component is defined as the sum of the intensities of the second harmonic, third harmonic, and fourth harmonic. The intensity ratio is calculated by dividing the intensity of the harmonic component by the intensity of the fundamental wave component.

Moreover, the order of harmonics included in the intensity of harmonic component is not limited to the above-mentioned. It is acceptable if the intensity of any of the second to fourth harmonics is not included, and the intensity of fifth or higher order harmonics may be included. Also, the intensity of harmonic component may be the intensity of a single order harmonic.

Next, the voltage of the DC component in the drive voltage is increased by one step (S23). If the increase amount of the voltage of the DC component is too small, the change in intensity of the harmonic component becomes too small, resulting in decreased determination accuracy of the reference voltage, and if the increase amount of the voltage of the DC component is too large, the error in the reference voltage becomes large. Therefore, it is desirable that the amount of change in the voltage of the DC component that the supply unit 90a increases in step S23 be approximately 1V. However, the increase amount of the voltage of the DC component is not limited to the above, and may be approximately 0.5V or may be approximately 1.5V.

Next, the output current is detected, and the intensity ratio of the harmonic component to the fundamental wave component of the resonant frequency fr is calculated (S24). Similar to step S22, the intensity of the harmonic component is divided by the intensity of the fundamental wave component to calculate the intensity ratio.

Next, it is determined whether or not the rate of change of the intensity ratio exceeds a threshold value (S25). The intensity ratio calculated in step S24 is divided by the intensity ratio calculated in step S22 to calculate the rate of change of the intensity ratio. When the rate of change of the intensity ratio exceeds the threshold value, it is determined that the pair of arm units 72a and 72b have switched from a closed state to an open state. The threshold value is, for example, a value set in advance, and is set to any value of 10% or more and 60% or less, for example.

Moreover, the threshold value for the rate of change of the intensity ratio may be a value determined during calibration. For example, the threshold value may be determined based on the average value, maximum value, or median value of the rate of change of the intensity ratio when the voltage of the DC component is increased in any number of stages while the pair of arm units 72a and 72b are certainly in a closed state. For instance, the threshold value may be set to a multiple such as 2 times or 3 times the average value, maximum value, or median value of the aforementioned rate of change of the intensity ratio.

In the case where the rate of change of the intensity ratio does not exceed the threshold value (NO in S25), the process returns to step S23, the voltage of the DC component in the drive voltage is further increased by one level, and in step S24, the intensity ratio of the harmonic component to the fundamental wave component of the resonant frequency fr is calculated. Then, in step S25, the rate of change of the intensity ratio before and after the change in the voltage of the DC component is calculated, and it is determined whether or not the rate of change of the intensity ratio exceeds the threshold value. In this way, the calculation of the rate of change of the intensity ratio when the voltage of the DC component is increased in 1V increments is repeated, and when it is determined that the rate of change of the intensity ratio exceeds the threshold value (YES in S25), based on the determination result, the voltage of the DC component before the increase is registered as the reference voltage for the start of opening (S26).

In the example shown in FIG. 9, the voltage of the DC component is 66V, and the intensity ratio of the harmonic component including the second harmonic f2, third harmonic f3, and fourth harmonic f4 to the fundamental wave component is approximately 3.777%. Additionally, when the voltage of the DC component is increased from 65V to 66V, the rate of change in the intensity ratio is approximately −3.038%. In the example shown in FIG. 10, the voltage of the DC component is 67V, and the intensity ratio of the harmonic component to the fundamental wave component is approximately 6.138%. When the voltage of the DC component is increased from 66V to 67V, the rate of change in the intensity ratio is approximately 62.496%. As such, when the pair of arm units 72a and 72b switch from a closed state to an open state, the rate of change in the intensity ratio becomes significantly larger compared to the previous rate of change. Incidentally, when the voltage of the DC component is 40V, the intensity ratio is approximately 2.935%, and when the voltage of the DC component is 41V, the intensity ratio is approximately 3.199%. When the voltage of the DC component is increased from 40V to 41V, the rate of change in the intensity ratio is approximately 8.988%. In the range where the pair of arm units 72a and 72b are in a closed state, the intensity ratio is small and thus susceptible to influences such as noise, and the rate of change in the intensity ratio can take either positive or negative values. However, when the pair of arm units 72a and 72b switch from a closed state to an open state, the rate of change in the intensity ratio becomes a large positive value.

Next, referring to FIG. 8, a method for registering the reference voltage at the start of opening and the rate of change of the opening/closing amount when the pair of arm units 72a and 72b clamp a calibration jig will be described. It should be noted that descriptions for operations similar to the operations already described in steps S21 to S26 will be omitted as appropriate.

First, a calibration jig is set between the pair of arm units 72a and 72b (S31), and a reference voltage at the start of opening when clamping the calibration jig is registered (S32). In step S32, steps S21 to S26 are executed.

Next, a voltage difference of the reference voltage at the start of opening due to the presence or absence of the calibration jig is calculated (S33). The reference voltage at the start of opening differs between the case where the pair of arm units 72a and 72b do not clamp anything and the case where the pair of arm units 72a and 72b clamp the calibration jig. This is because when clamping the calibration jig, the pair of arm units 72a and 72b in the closed state are separated from each other by the dimension of the calibration jig in the opening/closing direction. The reference voltage at the start of opening when clamping the calibration jig is larger than the reference voltage at the start of opening when clamping nothing. Therefore, the voltage difference of the reference voltage at the start of opening is calculated by subtracting the reference voltage at the start of opening when clamping nothing registered in step S26 from the reference voltage at the start of opening when clamping the calibration jig registered in step S32.

Next, the rate of change of the opening/closing amount of the pair of arm units 72a and 72b with respect to the applied voltage at the start of opening of the pair of arm units 72a and 72b is calculated (S34). The voltage difference calculated in step S33 corresponds to the additional applied voltage to the piezoelectric element 80 when changing the opening/closing amount of the pair of arm units 72a and 72b by the dimension of the calibration jig in the opening/closing direction. Here, the opening/closing amount of the pair of arm units 72a and 72b is the mutual distance between the clamp pieces 71a and 71b in the opening/closing direction. The rate of change of the opening/closing amount of the pair of arm units 72a and 72b with respect to the applied voltage is calculated by dividing the dimension of the calibration jig in the opening/closing direction by the voltage difference calculated in step S33.

Next, the rate of change of the opening/closing amount of the pair of arm units 72a and 72b at the start of opening is registered (S35). The rate of change of the opening/closing amount calculated in step S34 is stored in the memory of the wire bonding control unit 90.

Next, referring to FIG. 11, a method for registering a reference voltage at the end of closing when the pair of arm units 72a and 72b do not clamp anything will be described. It should be noted that descriptions may be omitted as appropriate for content similar to the content already described in steps S21 to S26.

First, the frequency of the AC component in the drive voltage is set to the resonant frequency fr, and the voltage of the DC component is set to a voltage at which the pair of arm units 72a and 72b are in an open state (S41). The difference between step S41 and step S21 is that the voltage of the DC component of the drive voltage is set to a voltage at which the pair of arm units 72a and 72b are in an open state rather than a closed state. For example, the voltage of the DC component is set to 100V, and the voltage of the AC component is set to 5V.

Next, the output current is detected, and the intensity ratio of the harmonic component to the fundamental wave component of the resonant frequency fr is calculated (S42). Step S42 is similar to step S22.

Next, the voltage of the DC component in the drive voltage is lowered by one step (S43). The difference between step S43 and step S23 is that the voltage of the DC component is lowered rather than raised. The amount of change in the voltage of the DC component in step S43 is the same as in step S23, and is, for example, about 1V.

Next, the output current is detected, and the intensity ratio of the harmonic component to the fundamental wave component of the resonant frequency fr is calculated (S44). Step S44 is similar to step S24.

Next, it is determined whether or not the rate of change of the intensity ratio exceeds a threshold value (S45), and based on the determination result, the voltage of the DC component before lowering is registered as the reference voltage for the end of closing (S46). The difference between step S45 and step S25 is that the threshold value set is different, and the threshold value in step S45 is set to zero, for example.

Specifically, as the pair of arm units 72a, 72b approaches from an open state to a closed state, the intensity of the harmonic component decreases, so the rate of change in the intensity ratio due to voltage drop becomes a negative value. However, immediately after switching to a closed state, the rate of change in the intensity ratio becomes a positive value because the balance between input and response changes due to the change in the open/close state of the pair of arm units 72a and 72b. After the pair of arm units 72a and 72b reaches a closed state, the rate of change in the intensity ratio randomly alternates between a positive value and a negative value. As an example, when the voltage of the DC component is 57V, the intensity ratio is about 6.383%, and when the voltage of the DC component is lowered from 58V to 57V, the rate of change in the intensity ratio is about −13.314%. When the voltage of the DC component is 56V, the intensity ratio is about 5.303%, and when the voltage of the DC component is lowered from 57V to 56V, the rate of change in the intensity ratio is about −16.933%. When the voltage of the DC component is 52V, the intensity ratio is about 3.540%, and when the voltage of the DC component is lowered from 53V to 52V, the rate of change in the intensity ratio is about −22.834%. When the voltage of the DC component is 51V, the intensity ratio is about 3.591%, and when the voltage of the DC component is lowered from 52V to 51V, the rate of change in the intensity ratio is about 1.420%. In the above case, when the voltage of the DC component is 52V, the pair of arm units 72a and 72b has finished closing, and the intensity ratio no longer decreases further, so even when the voltage of the DC component is lowered from 52V to 51V, the intensity ratio did not decrease. Therefore, the voltage of 52V before lowering, when the rate of change in the intensity ratio becomes a positive value, is registered as the reference voltage for the end of closing.

Moreover, the threshold value for the rate of change of the intensity ratio at the end of closing is not limited to zero. For example, if the rate of change of the intensity ratio changes within the above-mentioned range, the threshold value may be set to any value from −10% or more to 1% or less. Additionally, in the step of determining the open/close state of the pair of arm units 72a and 72b at the end of closing, the open/close state may be determined based on whether the absolute value of the rate of change of the intensity ratio is below the threshold value. Specifically, when the absolute value of the rate of change of the intensity ratio is larger than the threshold value, it may be determined that the pair of arm units 72a and 72b are in an open state, and when the absolute value of the rate of change of the intensity ratio is smaller than the threshold value, it may be determined that the pair of arm units 72a and 72b are in a closed state. This is because when the pair of arm units 72a and 72b are in an open state and approaching a closed state, the rate of change of the intensity ratio is large, but when the pair of arm units 72a and 72b are in a closed state, the intensity ratio hardly changes, that is, the rate of change of the intensity ratio becomes small.

Next, referring to FIG. 12, a method for registering the reference voltage at the end of closing and the rate of change of the opening/closing amount when the pair of arm units 72a and 72b clamp a calibration jig will be described. It should be noted that descriptions for operations similar to the operations already described in steps S31 to S35 will be omitted as appropriate.

First, a calibration jig is set between the pair of arm units 72a and 72b (S51), and a reference voltage at the end of closing when clamping the calibration jig is registered (S52). In step S52, steps S41 to S46 are executed.

Next, a voltage difference of the reference voltage at the end of closing due to the presence or absence of the calibration jig is calculated (S53). The voltage difference of the reference voltage at the end of closing is calculated by subtracting the reference voltage at the end of closing when clamping nothing registered in step S46 from the reference voltage at the end of closing when clamping the calibration jig registered in step S52.

Next, at the end of closing of the pair of arm units 72a and 72b, the rate of change of the opening/closing amount of the pair of arm units 72a and 72b with respect to the applied voltage is calculated (S54). Step S54 is similar to step S34.

Next, the rate of change of the opening/closing amount of the pair of arm units 72a and 72b at the end of closing is registered (S55). Step S55 is similar to step S35.

Finally, the operating voltage is calibrated (S36). Based on the registered reference voltage and rate of change of the opening/closing amount at the start of opening, and the reference voltage and rate of change of the opening/closing amount at the end of closing of the pair of arm units 72a and 72b, the operating voltage is calibrated. By executing the wire bonding process using the wire clamp device 70 with the calibrated operating voltage, the opening/closing operation of the pair of arm units 72a and 72b of the wire clamp device 70 corresponding to the operating voltage can be accurately grasped. Therefore, a high-precision and stable wire bonding process can be performed.

The calibration method is preferably performed each time the aspect of the wire bonding process differs, for example, when performing wire bonding with wires of different diameters, or when performing wire bonding in different temperature environments. This is particularly effective because the calibration method allows calibration according to the ease of opening of the wire clamp device 70 corresponding to each of situations.

Moreover, in steps S31 to S35 and steps S51 to S55, instead of the calibration jig, the wire 42 that is scheduled to be used for wire bonding after calibration may be used.

The following describes part or all of the embodiments of the present invention. It should be noted that the present invention is not limited to the following notes.

### [Note 1]

A clamp device 70 includes: a pair of arm units 72a and 72b for clamping a wire 42; a drive unit 76 having a piezoelectric element 80 for opening and closing the pair of arm units 72a and 72b; a supply unit 90a which is configured to generate a drive voltage in which an AC component with a variable frequency and a DC component with a variable voltage are superimposed, and to supply the drive voltage to the piezoelectric element 80, and in which the supply unit 90a increases or lowers the voltage of the DC component while setting the frequency of the AC component to a resonant frequency of the pair of arm units 72a and 72b; a detection unit 90b for detecting an output signal output from the driven piezoelectric element 80; and a determination unit 90c for determining an open/close state of the pair of arm units 72a and 72b based on an occurrence situation of a harmonic component of the resonant frequency in the output signal.

According to [Note 1], the open/close state of the pair of arm units 72a and 72b is determined based on the occurrence situation of the harmonic component in the output signal, therefore, in the determination of the open/close state, the influence of machine differences such as ease of vibration, ease of vibration transmission, and ease of output signal detection can be reduced.

### [Note 2]

The clamp device according to [Note 1] further includes a registration unit 90d that registers a voltage of the DC component when the pair of arm units 72a and 72b switch between an open state and a closed state as a reference voltage, and a calibration unit 90e that calibrates an operating voltage to be applied to the piezoelectric element 80 based on the reference voltage.

According to the aspect of [Note 2], based on the determination result of the open/close state with high accuracy, calibration with high accuracy may be performed, therefore, accuracy improvement and stabilization of the opening/closing operation of the clamp device 70 can be attempted.

### [Note 3]

The detection unit 90b detects an output current output from the piezoelectric element 80 as an output signal in the clamp device 70 according to [Note 2].

According to the aspect of [Note 3], the output current from the pair of arm units 72a and 72b can be expressed using a time derivative of an output voltage, so even if a change in magnitude that is difficult to detect as the output voltage may become a change in magnitude that can be detected as the output current. Therefore, the detection accuracy of the detection unit 90b can be improved, and the accuracy of the calibration can be enhanced.

### [Note 4]

The determination unit 90c calculates the intensity of a harmonic component of a resonant frequency in the output signal by performing a Fourier transform on the output current in the clamp device 70 according to [Note 3].

According to the aspect of [Note 4], components included in the output signal can be separated based on a frequency, and the intensity of each of the components can be compared.

### [Note 5]

The determination unit 90c calculates an intensity ratio of the harmonic component to a fundamental wave component of the resonant frequency in the output signal in the clamp device 70 according to [Note 4].

According to the aspect of [Note 5], an open/close state may be determined based on the intensity ratio, which is easier to compare than the harmonic component that is susceptible to noise influence, and the determination accuracy may be improved.

### [Note 6]

The determination unit 90c calculates a rate of change of the intensity ratio with respect to voltage change of the DC component in the clamp device 70 according to [Note 5].

According to the aspect of [Note 6], the open/close state may be determined based on the rate of change of the intensity ratio, which is easier to compare than the intensity ratio that is susceptible to noise influence, and the determination accuracy may be improved.

### [Note 7]

The registration unit 90d registers a first voltage as the reference voltage when the rate of change of the intensity ratio when the voltage of the DC component is changed from the first voltage to a second voltage exceeds a threshold value in the clamp device 70 according to [Note 6].

According to the aspect of [Note 7], when the pair of arm units 72a and 72b switch between an open state and a closed state, the rate of change of the intensity ratio changes significantly, therefore, the first voltage when the rate of change of the intensity ratio exceeds the threshold value can be set as the reference voltage.

### [Note 8]

The registration unit 90d, in a case where the pair of arm units 72a and 72b are in contact with each other in a closed state, registers the voltage of the DC component when the pair of arm units 72a and 72b switch from a closed state to an open state as a reference voltage for the start of opening of the pair of arm units 72a and 72b, and registers the voltage of the DC component when the pair of arm units 72a and 72b switch from an open state to a closed state as a reference voltage for the end of closing of the pair of arm units 72a and 72b in the clamp device 70 according to any one of [Note 2] to [Note 7].

According to the aspect of [Note 8], by registering both the reference voltage at the start of opening and the reference voltage at the end of closing, both the operating voltage when opening and the operating voltage when closing of the pair of arm units 72a and 72b may be calibrated, thereby attempting further accuracy improvement and stabilization of the opening/closing operation.

### [Note 9]

The registration unit 90d, in a case where the pair of arm units 72a and 72b clamp a calibration jig having higher dimensional accuracy than the wire 42 in a closed state, registers the voltage of the DC component when the pair of arm units 72a and 72b switch from a closed state to an open state as a reference voltage for the start of opening of the pair of arm units 72a and 72b, and registers the voltage of the DC component when the pair of arm units 72a and 72b switch from an open state to a closed state as a reference voltage for the end of closing of the pair of arm units 72a and 72b in the clamp device 70 according to any one of [Note 2] to [Note 7].

According to the aspect of [Note 9], by registering both the reference voltage at the start of opening and the reference voltage at the end of closing when clamping the calibration jig, both the operating voltage when opening and the operating voltage when closing of the pair of arm units 72a and 72b may be calibrated, thereby attempting further accuracy improvement and stabilization of the opening/closing operation. By clamping the calibration jig with higher dimensional accuracy than the wire 42 when determining the reference voltage, the calibration accuracy can be improved compared to clamping the wire 42.

### [Note 10]

The registration unit 90d, in a case where the pair of arm units 72a and 72b clamp the wire 42 in a closed state, registers the voltage of the DC component when the pair of arm units 72a and 72b switch from a closed state to an open state as a reference voltage for the start of opening of the pair of arm units 72a and 72b, and registers the voltage of the DC component when the pair of arm units 72a and 72b switch from an open state to a closed state as a reference voltage for the end of closing of the pair of arm units 72a and 72b in the clamp device 70 according to any one of [Note 2] to [Note 7].

According to the aspect of [Note 10], by registering both the reference voltage at the start of opening and the reference voltage at the end of closing when clamping the wire 42, both the operating voltage when opening and the operating voltage when closing of the pair of arm units 72a and 72b may be calibrated, thereby attempting further accuracy improvement and stabilization of the opening/closing operation. By clamping the workpiece when determining the reference voltage, compared to clamping the calibration jig, the configuration of the clamp device and the calibration process may be simplified.

### [Note 11]

The registration unit 90d registers, in a case where the pair of arm units 72a and 72b are in contact with each other in a closed state, the voltage of the DC component when the pair of arm units 72a and 72b switch between an open state and a closed state as a first reference voltage, and registers, in a case where the pair of arm units 72a and 72b clamp a calibration jig having higher dimensional accuracy than the wire 42 or the wire 42 in a closed state, the voltage of the DC component when the pair of arm units 72a and 72b switch between an open state and a closed state as a second reference voltage, and calculates and registers a rate of change of the opening/closing amount of the pair of arm units 72a and 72b with respect to the voltage applied to the piezoelectric element 80 based on the voltage difference between the first reference voltage and the second reference voltage and the dimension of the calibration jig or the wire 42 in the opening/closing direction of the pair of arm units 72a and 72b, and the calibration unit 90e calibrates the operating voltage applied to the piezoelectric element 80 based on the rate of change of the opening/closing amount in the clamp device 70 according to any one of [Note 2] to [Note 7].

According to the aspect of [Note 11], by calibrating the opening/closing amount of the pair of arm units 72a and 72b with respect to the operating voltage, further accuracy improvement and stabilization of the opening/closing operation can be attempted.

### [Note 12]

The harmonic component of the resonant frequency include components of multiple harmonics in the clamp device 70 according to any one of [Note 1] to [Note 11].

According to the aspect of [Note 12], since the determination accuracy of the open/close state of the pair of arm units 72a and 72b based on the harmonic component is improved, the accuracy of calibration is enhanced, and further accuracy improvement and stabilization of the opening/closing operation can be attempted.

### [Note 13]

The supply unit 90a sets the voltage of the DC component to a voltage at which the pair of arm units 72a an 72b are in an open state, and increases or lowers the frequency of the AC component, the determination unit 90c determines the resonance state of the pair of arm units 72a and 72b based on the occurrence situation of components caused by collision of the pair of arm units 72a and 72b in the output signal, and the registration unit 90d registers the frequency of the AC component when the resonance state of the pair of arm units 72a and 72b becomes strongest as the resonant frequency of the pair of arm units 72a and 72b in the clamp device 70 according to any one of [Note 1] to [Note 12].

According to the aspect of [Note 13], even in cases where the resonant frequency fluctuates due to machine differences or time-dependent changes, the resonant frequency of the pair of arm units 72a and 72b before executing the calibration may be determined. Therefore, the accuracy of the calibration can be improved, and further accuracy improvement and stabilization of the opening/closing operation can be attempted.

### [Note 14]

A control method for a wire clamp device 70 which includes a pair of arm units 72a and 72b for clamping a wire 42, a drive unit 76 having a piezoelectric element 80 for opening and closing the pair of arm units 72a and 72b, and a supply unit 90a configured to generate a drive voltage in which an AC component with a variable frequency and a DC component with a variable voltage are superimposed, and to supply the drive voltage to the piezoelectric element 80 includes: the frequency of the AC component is set to a resonant frequency of the pair of arm units 72a and 72b and the voltage of the DC component is increased or lowered; an output signal output from the driven piezoelectric element 80 is detected; and an open/close state of the pair of arm units 72a and 72b is determined based on an occurrence situation of a harmonic component of the resonant frequency in the output signal.

According to the aspect of [Note 14], the open/close state of the pair of arm units 72a and 72b is determined based on the occurrence situation of the harmonic component in the output signal, therefore, in the determination of the open/close state, the influence of machine differences such as ease of vibration, ease of vibration transmission, and ease of output signal detection can be reduced.

### [Note 15]

A control program for operating a wire clamp device 70 which includes a pair of arm units 72a and 72b for clamping a wire 42, a drive unit 76 having a piezoelectric element 80 for opening and closing the pair of arm units 72a and 72b, and a supply unit 90a configured to generate a drive voltage in which an AC component with a variable frequency and a DC component with a variable voltage are superimposed, and to supply the drive voltage to the piezoelectric element 80 causes a computer to execute: setting the frequency of the AC component to a resonant frequency of the pair of arm units 72a and 72b and increasing or lowering the voltage of the DC component; detecting an output signal output from the driven piezoelectric element 80; and determining an open/close state of the pair of arm units 72a and 72b based on an occurrence situation of a harmonic component of the resonant frequency in the output signal.

According to the aspect of [Note 15], the open/close state of the pair of arm units 72a and 72b is determined based on the occurrence situation of the harmonic component in the output signal, therefore, in the determination of the open/close state, the influence of machine differences such as ease of vibration, ease of vibration transmission, and ease of output signal detection can be reduced.

As described above, according to an aspect of the present invention, improvement of determination accuracy of the open/close state of a pair of arm units can be attempted.

The embodiment described above is for facilitating understanding of the present invention, and is not intended to limit the interpretation of the present invention. The elements of the embodiment as well as their arrangement, materials, conditions, shapes, and sizes, etc. are not limited to those exemplified and can be modified as appropriate. Furthermore, configurations shown in different embodiments may be partially substituted or combined with each other.

### REFERENCE SIGNS LIST

1 wire bonding apparatus
70 wire clamp device
72a, 72b arm unit
73a, 73b tip unit
74a, 74b base end unit
76 drive unit
90 wire bonding control unit
90a supply unit
90b detection unit
90c determination unit
90d registration unit
90e calibration unit

1. A clamp device, comprising:
a pair of arm units, clamping a workpiece;
a drive unit, comprising a piezoelectric element which opens and closes the pair of arm units;
a supply unit, configured to generate a drive voltage in which an alternating current (AC) component with a variable frequency and a direct current (DC) component with a variable voltage are superimposed, and to supply the drive voltage to the piezoelectric element, and the supply unit increasing or lowering the voltage of the DC component with the frequency of the AC component set to a resonant frequency of the pair of arm units;
a detection unit, detecting an output signal output from the piezoelectric element that has been driven; and
a determination unit, determining an open/close state of the pair of arm units based on an occurrence situation of a harmonic component of the resonant frequency in the output signal.

2. The clamp device according to claim 1, further comprising:
a registration unit, registering the voltage of the DC component when the pair of arm units switch between an open state and an closed state as a reference voltage; and
a calibration unit, calibrating an operating voltage applied to the piezoelectric element based on the reference voltage.

3. The clamp device according to claim 2, wherein
the detection unit detects an output current output from the piezoelectric element as the output signal.

4. The clamp device according to claim 3, wherein
the determination unit calculates intensity of the harmonic component of the resonant frequency in the output signal by performing a Fourier transform on the output current.

5. The clamp device according to claim 4, wherein
the determination unit calculates an intensity ratio of the harmonic component to a fundamental wave component of the resonant frequency in the output signal.

6. The clamp device according to claim 5, wherein
the determination unit calculates a rate of change of the intensity ratio with respect to a voltage change of the DC component.

7. The clamp device according to claim 6, wherein
the registration unit registers a first voltage as a reference voltage when the rate of change of the intensity ratio when the voltage of the DC component is changed from the first voltage to a second voltage exceeds a threshold value.

8. The clamp device according to claim 2, wherein
the registration unit,
in a case where the pair of arm units are in contact with each other in a closed state,
registers the voltage of the DC component when the pair of arm units switch from a closed state to an open state as a reference voltage for a start of opening of the pair of arm units, and
registers the voltage of the DC component when the pair of arm units switch from an open state to a closed state as a reference voltage for an end of closing of the pair of arm units.

9. The clamp device according to claim 2, wherein
the registration unit,
in a case where the pair of arm units clamp a calibration jig with higher dimensional accuracy than the workpiece in a closed state,
registers the voltage of the DC component when the pair of arm units switch from a closed state to an open state as a reference voltage for a start of opening of the pair of arm units, and
registers the voltage of the DC component when the pair of arm units switch from an open state to a closed state as a reference voltage for an end of closing of the pair of arm units.

10. The clamp device according to claim 2, wherein
the registration unit,
in a case where the pair of arm units clamp the workpiece in a closed state,
registers the voltage of the DC component when the pair of arm units switch from a closed state to an open state as a reference voltage for a start of opening of the pair of arm units, and
registers the voltage of the DC component when the pair of arm units switch from an open state to a closed state as a reference voltage for an end of closing of the pair of arm units.

11. The clamp device according to claim 2, wherein
the registration unit,
in a case where the pair of arm units are in contact with each other in a closed state, registers the voltage of the DC component when the pair of arm units switch between an open state and a closed state as a first reference voltage,
in a case where the pair of arm units clamp a calibration jig with higher dimensional accuracy than the workpiece or the workpiece in a closed state, registers the voltage of the DC component when the pair of arm units switch between an open state and a closed state as a second reference voltage, and
calculates and registers a rate of change of an opening/closing amount of the pair of arm units with respect to the voltage applied to the piezoelectric element based on a voltage difference between the first reference voltage and the second reference voltage and a dimension of the calibration jig or the workpiece in an opening/closing direction of the pair of arm units, and
the calibration unit calibrates the operating voltage applied to the piezoelectric element based on the rate of change of the opening/closing amount.

12. The clamp device according to claim 1, wherein
the harmonic component of the resonant frequency comprises components of a plurality of harmonics.

13. The clamp device according to claim 2, wherein
the supply unit increases or lowers the frequency of the AC component with the voltage of the DC component set to a voltage at which the pair of arm units are in an open state,
the determination unit determines a resonance state of the pair of arm units based on an occurrence situation of components due to collision of the pair of arm units in the output signal, and
the registration unit registers the frequency of the AC component when the resonance state of the pair of arm units is strongest as the resonant frequency of the pair of arm units.

14. A control method for a clamp device which comprises
a pair of arm units that clamp a workpiece,
a drive unit comprising a piezoelectric element that opens and closes the pair of arm units, and
a supply unit configured to generate a drive voltage in which an AC component with a variable frequency and a DC component with a variable voltage are superimposed and to supply the drive voltage to the piezoelectric element, the control method comprising:
increasing or lowering the voltage of the DC component with the frequency of the AC component set to a resonant frequency of the pair of arm units,
detecting an output signal output from the piezoelectric element that has been driven,
determining an open/close state of the pair of arm units based on an occurrence situation of a harmonic component of the resonant frequency in the output signal.

15. A recording medium recording a control program for operating a clamp device which comprises
a pair of arm units that clamp a workpiece,
a drive unit comprising a piezoelectric element that opens and closes the pair of arm units, and
a supply unit configured to generate a drive voltage in which an AC component with a variable frequency and a DC component with a variable voltage are superimposed and to supply the drive voltage to the piezoelectric element,
the control program causing a computer to execute:
increasing or lowering the voltage of the DC component with the frequency of the AC component set to a resonant frequency of the pair of arm units,
detecting an output signal output from the piezoelectric element that has been driven,
determining an open/close state of the pair of arm units based on an occurrence situation of a harmonic component of the resonant frequency in the output signal.
